(19) United States
(12) Patent Application Publication
(10) Pub. No.: US 2018/0053829 A1
(43) Pub. Date: Feb. 22, 2018

(54) METHOD OF FORMING A SEMICONDUCTOR DEVICE AND SEMICONDUCTOR DEVICE

(71) Applicant: GLOBALFOUNDRIES Inc., Grand Cayman (KY)

(72) Inventors: Elliot John Smith, Dresden (DE); Sylvain Henri Baudot, Dresden (DE); Peter Javorka, Radeburg (DE); Gerd Zschaetzsch, Dresden (DE)

(21) Appl. No.: 15/242,689

(22) Filed: Aug. 22, 2016

(51) Int. Cl. H01L 29/423; H01L 29/78; H01L 29/06; H01L 29/08; H01L 29/66; H01L 21/28

(52) U.S. Cl. CPC H01L 29/42376; H01L 29/7838; H01L 21/28114; H01L 29/0847; H01L 29/66651; H01L 29/0649

(57) ABSTRACT

A method of forming a semiconductor device is provided, wherein the method includes forming a shaped gate structure over an active region, the shaped gate structure comprising a gate dielectric layer and a gate electrode disposed on the gate dielectric layer, and forming raised source/drain regions adjacent to the gate structure, the raised source/drain regions being formed at opposing sides of the shaped gate structure relative to a length direction of the shaped gate structure, wherein the gate electrode has a tapering shape according to which a dimension of the gate electrode along the length direction varies from a maximum value at a lower portion of the gate electrode close to the gate dielectric layer towards a minimal value at a top portion of the gate electrode.

### BACKGROUND

### 1. Field of the Disclosure

The present disclosure generally relates to a method of forming a semiconductor device and to a semiconductor device, particularly at advanced technology nodes.

### 2. Description of the Related Art

In modern electronic equipment, integrated circuits (ICs) experience a vast applicability in a continuously spreading range of applications. Particularly, the demand for increasing mobility of electronic devices at high performance and low energy consumption drives developments to more and more compact devices having features with sizes ranging even into the deep sub-micron regime; and more so as current semiconductor technologies are apt to produce structures with dimensions on the order of 10 nm. With ICs representing a set of electronic circuit elements integrated on a semiconductor material, normally silicon, ICs can be made much smaller than discreet circuits composed of independent circuit components. The majority of present-day ICs are implemented by using a plurality of circuit elements, such as field effect transistors (FETs), also called metal oxide semiconductor field effect transistors (MOSFETs or simply MOS transistors), and passive elements, such as resistors and capacitors, integrated on a semiconductor substrate with a given surface area. Typically, present-day integrated circuits involve millions of single circuit elements formed on a semiconductor substrate.

The basic function of a FET or a MOSFET is that of an electronic switching element, wherein a current through a channel region between two contact regions, referred to as source and drain, is controlled by a gate electrode, which is disposed over the channel region and to which a voltage relative to source and drain is applied. Particularly, in applying a voltage exceeding a characteristic voltage level to the gate electrode, the conductivity state of a MOSFET is changed and the characteristic voltage level, usually called “threshold voltage” and in the following referred to as Vt, characterizes the switching behavior of a MOSFET. In general, Vt depends nontrivially on the transistor's properties, e.g., materials, dimensions, etc., such that the implementation of a desired Vt involves plural steps of adjustment and fine-tuning during the fabrication process.

With the continuous scaling down to increasingly small technology nodes in the deep sub-micron regime (at present at 22 nm and beyond), various issues and challenges arise. For example, a precise control of the electrical conductivity of the channel of a MOS transistor is difficult to maintain at very small process geometries. Since the switching behavior of a MOSFET is characterized by the threshold voltage Vt of a MOSFET, the precise setting of a definition and control of the threshold Vt throughout the fabrication process of semiconductor devices is essential for achieving optimal power consumption and performance of semiconductor device structures. In general, there are several factors which control the threshold voltage Vt, such as the gate oxide thickness, the work function of the gate and the channel doping, mainly representing independent factors. The scaling of a semiconductor device to more advanced technology nodes leads to faster switching and higher current drive behaviors or advanced semiconductor devices, at the expense, however, of a decreased noise margin, increased leakage current and increased power.

Most of the digital integrated circuits built today use CMOS technology, which is fast and offers a high circuit density and low power per gate. CMOS devices or “complementary symmetry metal oxide semiconductor” devices, as sometimes referred to, make use of complementary and symmetrical pairs of P-type and N-type MOSFETs. Two important characteristics of CMOS devices are the high noise immunity and low static power consumption of a CMOS device because the series combination of complementary MOSFETs in a CMOS device draws significant power only momentarily during switching between on- and off-states, since one transistor of a CMOS device is always in the off-state. Consequently, CMOS devices do not produce as much waste heat as other forms of semiconductor devices, for example, transistor-transistor logic (TTL) or NMOS logic devices, which normally have some standing current even when not changing state. In current CMOS technologies, standard transistors and IO devices have the same high-k dielectric and metal electrode, whereas, in comparison with standard devices, the SiO₂ oxide of I/O devices is thicker.

Scaling of gate dielectrics of MOS devices is an increasing challenge when seeking to improve the performance of complex MOS devices. At strongly scaled MOS devices in the deep sub-micron regime, the parasitic gate capacitance of the gate of a MOS device has an increasing effect on the performance of a MOS device by reducing the switching speed of the MOS device. The reason is that the capacitive coupling of a gate electrode to adjacent circuit components limits the rate at which the voltage of the gate electrode may be changed. The delay in the changes in the gate voltage due to the capacitive coupling with adjacent circuit components then leads to an increased turn-on time and turn-off time of a MOS device.

Generally, MOS devices are prone to this type of parasitic capacitive coupling to adjacent circuit components by design because, due to the increased scaling of MOS devices, the gate electrodes and adjacent circuit components and MOS device elements, e.g., source and/or drain, source contacts and/or drain contacts, contact vias to source and/or drain and the like, come closer to the gate electrode and, therefore, increase the parasitic capacitance between the gate electrode and the adjacent circuit components and MOS device elements due to their physical proximity.

Since the gate electrode and the MOS device elements are physical structures, the parasitic capacitance between the gate electrode and MOS device elements may be reduced by scaling the dimensions of the gate electrode, the MOS device elements or of both. However, the scaling of the gate electrode and/or of adjacent MOS device elements leads again to additional problems, such as landing issues for landing on source/drain regions with via contacts and/or landing on the gate electrode with a gate contact.

A popular approach considered in the development of complex semiconductor devices is the semiconductor-on-insulator (SOI) technology, where a layered silicon-insulator-silicon substrate is used in place of conventional bulk substrates in the fabrication of semiconductor devices, e.g., in microelectronics. As an implementation of one of several manufacturing strategies employed to allow the continued miniaturization of microelectronic devices, the SOI technology promises lower parasitic capacitances due to an isolation of semiconductor devices fabricated on a silicon layer that is isolated from the silicon substrate by means of an insulator layer, therefore, improving power consumption at match performance. According to recent efforts to comply with Moore's Law, a fully depleted SOI (FDSOI) technique is followed, according to which a thickness of the silicon layer over the silicon substrate is very thin so that the depletion region of FDSOI devices covers the entire silicon layer. As herein, the front gate of MOS devices supports less depletion charges as compared to bulk technologies, an increase in inversion charges occurs and higher switching speeds are obtained.

Upon reducing the thickness of the active silicon layer in FDSOI technology, very thin channel regions (referred to as ultra-thin channel (UTC) regions) are formed and the source/drain regions are at least partially formed above the active semiconductor layer and, therefore, above the channel region, leading to so-called “raised source/drain” (RSD) regions. However, as subjected to further scaling, the separation between RSD regions and gate electrodes within MOS devices is scaled, therefore, increasing the parasitic capacitance again in strongly scaled FDSOI technologies with UTC regions. In non-RSD technologies, parasitic capacitances are also an issue caused by the source/drain contact (CA) to gate electrode (PC) distances and efforts are directed to adjusting these distances for improvement.

However, in RSD technologies, this CA-PC distance plays less of a role because there is only a spacer structure in between RSD and the gate. Attempts to improve the parasitic capacitance by simply widening the spacer thickness for improvement as an expense of the gate length, results in the loss of control over the channel and, therefore, results in the loss of performance. Accordingly, attempts lead to much larger issues to be able to lower these capacitances.

For example, there are attempts to reduce the parasitic capacitance introduced by RSD regions in FDSOI technologies at advanced technology nodes by reducing the capacitive coupling between RSD regions and the gate electrodes when using spacers comprising a low-k material, e.g., SiBCN, having k values lower than 4. In accordance with other current attempts, the RSD regions are shortened and/or faceted. These proposals increase the complexity of fabrication process flows, show a low controllability in the mass production and do not fully deliver the required reduction in the parasitic capacitance as needed for high speed RF applications, for example.

In view of the above explanations, there is a need in the art for improving existing implementations of semiconductor devices with regard to parasitic capacitance at advanced technology nodes.

### SUMMARY OF THE DISCLOSURE

The following presents a simplified summary of the disclosure in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure provides a method of forming a semiconductor device. In accordance with some illustrative embodiments herein, the method includes forming a shaped gate structure over an active region, the shaped gate structure comprising a gate dielectric layer and a gate electrode disposed on the gate dielectric layer, and forming raised source/drain regions adjacent to the gate structure, the raised source/drain regions being formed at opposing sides of the shaped gate structure relative to a length direction of the shaped gate structure, wherein the gate electrode has a tapering shape according to which a dimension of the gate electrode along the length direction varies from a maximum value at a lower portion of the gate electrode close to the gate dielectric layer towards a minimal value at a top portion of the gate electrode.

In another aspect of the present disclosure, a semiconductor device is provided. In accordance with some illustrative embodiments herein, the semiconductor device includes a semiconductor substrate with an active region, a shaped gate structure formed over the active region, the shaped gate structure comprising a gate dielectric layer and a gate electrode disposed over the gate dielectric layer, and raised source/drain regions formed adjacent to the gate structure, the raised source/drain regions being formed at opposing sides of the shaped gate structure relative to a length direction of the shaped gate structure, wherein the gate electrode has a tapering shape according to which a dimension of the gate electrode along the length direction varies from a maximum value at a lower portion of the gate electrode close to the gate dielectric layer towards a minimal value at a top portion of the gate electrode.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c schematically illustrate semiconductor devices in accordance with various embodiments of the present disclosure;

FIGS. 2a-2e schematically illustrate ways of forming a semiconductor device in accordance with some illustrative embodiments of the present disclosure;

FIGS. 3a-3c schematically illustrate other ways of forming a semiconductor device in accordance with other illustrative embodiments of the present disclosure;

FIGS. 3d-3e schematically illustrate some alternatives to the embodiments depicted in FIGS. 3a-3c; and

FIGS. 4a-4b schematically illustrate still other ways of forming a semiconductor device in accordance with still other illustrative embodiments of the present disclosure.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

The present disclosure relates to a method of forming a semiconductor device and to semiconductor devices, wherein the semiconductor devices are integrated on or in a chip. In accordance with some illustrative embodiments of the present disclosure, the semiconductor devices may substantially represent FETs, e.g., MOSFETs or MOS devices. When referring to MOS devices, the person skilled in the art will appreciate that, although the expression “MOS device” is used, no limitation to a metal-containing gate material and/or to an oxide-containing gate dielectric material is intended.

Semiconductor devices of the present disclosure concern devices which may be fabricated by using advanced technologies, i.e., the semiconductor devices may be fabricated by technologies applied to approach technology nodes smaller than 100 nm, for example, smaller than 50 nm or smaller than 35 nm, e.g., at 22 nm or below. After a complete review of the present application, the person skilled in the art will appreciate that, according to the present disclosure, ground rules smaller or equal to 45 nm, e.g., at 22 nm or below, may be imposed but that the present invention is not limited to such examples. After a complete review of the present application, the person skilled in the art will also appreciate that the present disclosure may be employed in fabricating semiconductor devices with structures of minimal length dimensions and/or width dimensions smaller than 100 nm, for example, smaller than 50 nm or smaller than 35 nm or smaller than 22 nm. For example, the present disclosure may provide semiconductor devices fabricated by using 45 nm technologies or below, e.g., 22 nm or even below.

The person skilled in the art will appreciate that semiconductor devices may be fabricated as P-channel MOS transistors or PMOS transistors and N-channel transistors or NMOS transistors; both types of transistors may be fabricated with or without mobility-enhancing stressor features or strain-inducing features. It is noted that a circuit designer can mix and match device types, using PMOS and NMOS devices, stressed and unstressed, to take advantage of the best characteristics of each device type as they best suit the semiconductor device under design.

In accordance with some illustrative embodiments of the present disclosure, a semiconductor device structure may comprise at least one semiconductor device. In accordance with illustrative examples herein where a semiconductor device structure comprises two semiconductor devices, the two semiconductor devices may be separated by at least one intermediate isolation structure, e.g., a trench isolation structure (for example, a shallow trench isolation structure). In accordance with some other illustrative examples herein where a semiconductor device structure comprises three or more semiconductor devices, an isolation structure, e.g., a trench isolation structure (for example, a shallow trench isolation structure) may be disposed between two adjacent semiconductor devices.

In general, SOI devices have an active semiconductor layer disposed on a buried insulating material layer, which in turn is formed on a base substrate material. In accordance with some illustrative embodiments herein, the active semiconductor layer may comprise one of silicon, germanium, silicon germanium and the like. The buried insulating material layer may comprise an insulating material, e.g., silicon oxide or silicon nitride. The base substrate material may be a base material that may be used as a substrate as known in the art, e.g., silicon and the like. After a complete review of the present application, the person skilled in the art will appreciate that, in accordance with illustrative embodiments employing FDSOI substrates, the active semiconductor layer may have a thickness of about 20 nm or less, while the buried insulating material layer may have a thickness of about 145 nm or, in accordance with advanced techniques, the buried insulating material layer may have a thickness in a range from about 10-30 nm. For example, in some special illustrative embodiments of the present disclosure, the active semiconductor layer may have a thickness of about 6-10 nm.

As to a crystallographic plane orientation of the base substrate material, similar to that of an ordinary silicon device, an SOI substrate whose surface is a face (100) may be used. However, in order to improve the performance of a PMOS semiconductor device, a surface of the PMOS semiconductor device may be used as a face (110). Alternatively, a hybrid plane orientation substrate whose surface may be mixed by a face (100) and a face (110) may be used. With regard to a varactor device, there is no restriction on a crystal plane orientation such that an impurity concentration, film thickness, dimension ratio of the device and the like may be appropriately adjusted to obtain a capacitance characteristic that is suitable according to the plane orientation set by other requirements. In alternative embodiments, the base substrate material may be of an N-type when N-accumulation and/or N-inversion devices are considered (otherwise P-type for P-accumulation and/or P-inversion).

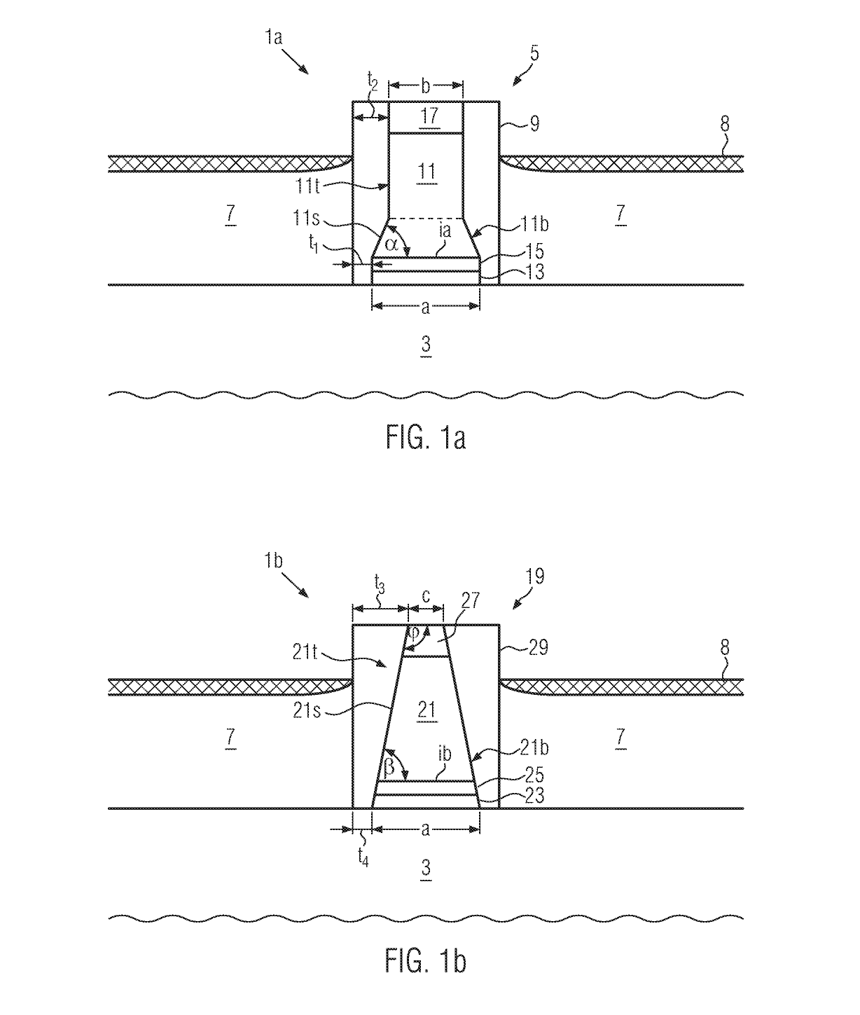

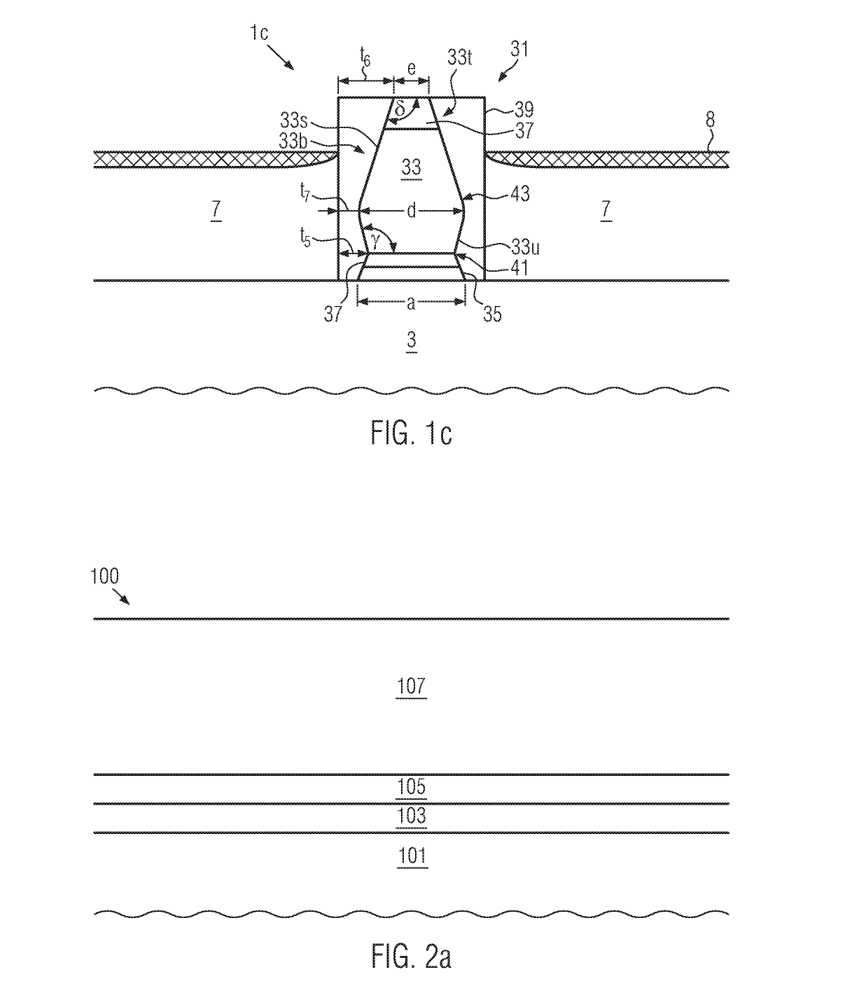

With regard to FIGS. 1a-1c, semiconductor devices will be described with regard to various illustrative embodiments of the present disclosure. FIG. 1a schematically shows a semiconductor device 1a comprising a shaped gate structure 5 formed over an active region of a substrate 3. The substrate 3 may be a substrate having an SOI configuration, comprising a base substrate (not illustrated), a buried insulating material (not illustrated) interposed between the base substrate (not illustrated) and an active semiconductor material (the illustrated portion of the substrate 3 in FIG. 1a may be an upper surface portion of an active semiconductor material) formed on the buried insulating material (not illustrated). In accordance with some special illustrative examples herein, the substrate 3 may be provided in accordance with FDSOI techniques, wherein a thickness of an active semiconductor material (in this case only illustrated as an upper surface portion of the substrate 3 in FIG. 1a) may have a thickness of about 20 nm or less, e.g., a thickness of about 6-10 nm.

In accordance with some illustrative embodiments of the present disclosure, raised source/drain regions 7 may be formed at opposing sides of the shaped gate structure 5. The raised source/drain regions 7 may have a contact portion 8, e.g., a silicide contact, for contacting the raised source/drain regions 7. A separation between the raised source/drain region 7 and the shaped gate structure 5 may be adjusted by means of a spacer structure 9. In accordance with some illustrative embodiments of the present disclosure, the spacer structure 9 may comprise at least one spacer, e.g., a “spacer zero,” an optional “spacer one” and at least one optional “spacer liner” and the like. The spacer structure 9 may be formed by at least one layer comprising a silicon oxide material and/or at least one layer comprising a silicon nitride material. In accordance with some illustrative examples, the spacer structure 9 may comprise a low-k material (k value less than 3.5), e.g., SiBCN.

In accordance with some illustrative embodiments of the present disclosure, the shaped gate structure 5 comprises a gate dielectric layer 13. For example, the gate dielectric layer 13 may be formed by a silicon oxide material and/or at least one high-k material (k value greater than 10), e.g., a hafnium oxide material, such as hafnium oxide, hafnium oxynitride or hafnium silicate. In some illustrative examples, at least one optional work function adjusting material layer 15 may be formed on the gate dielectric layer 13, e.g., a layer of TiN and the like.

In accordance with some illustrative embodiments of the present disclosure, a gate electrode 11 may be disposed over the gate dielectric layer 13, wherein the gate electrode 11 may be comprised of a conductive material, e.g., amorphous silicon, polysilicon, a metal or a metal alloy.

In accordance with some illustrative embodiments, the gate electrode 11 may comprise a lower portion 11b and an upper portion or top portion 11t. In the top portion 11t of the gate electrode 11, a gate contact 17, e.g., a silicide contact, may be formed. This does not pose any limitation on the present disclosure and, alternatively, reference numeral 17 may indicate a gate cap covering an exposed upper surface of the top portion 11t of the gate electrode 11.

Referring to FIG. 1a, the shaped gate structure 5 of the semiconductor device 1a may be formed over an active region of the substrate 3. The raised source/drain regions 7 may be formed at opposing sides of the shaped gate structure 5 relative to a gate length direction of the shaped gate structure 5, which gate length direction may be oriented in parallel to a direction as indicated by a double-arrow denoted with “a” in FIG. 1a. That is, the gate length direction corresponds to a direction extending between the raised source/drain regions 7.

With regard to FIG. 1a, the shaped gate structure 5 is shaped such that the gate electrode 11 has a tapering shape according to which a dimension of the gate electrode 11 along the length direction varies from a maximum value (see “a” in FIG. 1a and in the description below) at the lower portion 11b of the gate electrode 11 close to the gate dielectric layer 13 towards a minimal value (see “b” in FIG. 1a and in the description below) at a top portion 11t of the gate electrode 11, as will be explained below in greater detail.

In accordance with some illustrative embodiments of the present disclosure, a dimension of the gate electrode 11 at the top portion 11t of the gate electrode 11, e.g., a dimension of the gate electrode 11 at an upper surface or interface of the top portion 11t of the gate electrode 11 to the contact structure 17 (or gate cap) taken along a length dimension of the shaped gate structure 5, may be substantially smaller than an effective gate length of the shaped gate structure 5, that is, a dimension of the lower portion 11b of the gate electrode 11, e.g., a dimension of the shaped gate structure 1a at an interface between the gate electrode 11 and an underlying material layer, such as the gate dielectric layer 13 and/or the work function adjusting material layer 15. With regard to FIG. 1, reference numeral “a” indicates a dimension of the shaped gate structure 5 taken along the gate length of the shaped gate structure 5, the gate length being measured along a direction parallel to a channel region extending between the raised source/drain regions 7 in an upper surface portion of the substrate 3 below the shaped gate structure 5. The effective gate length “a” may substantially correspond to a maximum value of the gate electrode 11 taken at the lower portion 11b. Reference numeral “b” in FIG. 1a schematically indicates a dimension of the gate electrode 11 at the top portion 11t, e.g., at an interface of the top portion 11t and the contact structure 17 (or gate cap) along the gate length. According to the illustration in FIG. 1a, it is: a>b. In other words, the shaped gate structure 5 may have a lower portion 11b having a maximum value measured along the gate length of the shaped gate structure 5, and a dimension of the gate electrode 11 may decrease from the lower portion 11b to the top portion 11t of the gate electrode from the maximum value to a minimum value represented by reference numeral “b” in FIG. 1a. In accordance with some illustrative examples, a dimension of the gate electrode 11 taken along the gate length may decrease at the lower portion 11b, e.g., may linearly decrease at the lower portion 11b to a certain height level of the gate electrode 11 (indicated by a broken line in FIG. 1a) and may then substantially remain constant along the gate electrode 11 towards the top portion 11t at the minimum value “b”.

In accordance with some special illustrative examples herein, the maximum value “a” may be greater than 25 nm or greater than 30 nm. For example, the maximum value “a” may be in a range from about 25-40 nm, e.g., in a range from about 30-38 nm. In accordance with some explicit but non-limiting examples, the maximum value “a” may be in a range from about 33-37 nm.

In accordance with some special illustrative examples herein, the minimum value “b” may be smaller than 30 nm or smaller than 25 nm. For example, the minimum value “b” may be in a range from about 10-25 nm, e.g., in a range from about 15-23 nm.

In accordance with some illustrative embodiments, a dimension of the gate dielectric layer 13 and/or of the optional work function adjusting material layer 15 may be at the target critical dimension, e.g., 32 nm or 22 nm, while the gate electrode may have an equal or smaller maximum value due to the tapering of the gate electrode 11.

In accordance with some illustrative embodiments of the present disclosure, the lower portion 11b may have a tapering shape, e.g., linearly tapering shape, where a tilt angle α formed between a tapering sidewall surface 11s at the lower portion 11b is tilted relative to an interface “ia” between the gate electrode 11 and the next lower material layer (one of the material layers 13 and 15 in FIG. 1a) may be smaller than 90° (α<90°). In accordance with some illustrative embodiments herein, the tilt angle α may be greater than 60° (60°≦α). For example, the tilt angle α may be in a range from about 70-88° (70°≦α≦88°), or in a range from about 75-88° (75°≦α≦88°), or in a range from about 70-80° (70°≦α≦80°), or in a range from about 60-75° (60°≦α≦75°).

In accordance with some illustrative embodiments as depicted with regard to FIG. 1a, the semiconductor device 1a having the shaped gate structure 5 may have a substantially variable separation between the gate electrode 11 and the raised source/drain regions 7 provided by the spacer structure 9 having a variable thickness, that is, a thickness of the spacer structure 9 varying from a minimal thickness t₁ to a maximum thickness t₂ in accordance with the varying dimension of the gate electrode 11 which changes from the maximum value “a” to the minimum value “b”.

In accordance with some illustrative embodiments of the present disclosure, the height level, as indicated by a broken line in FIG. 1a, representing a transition between the top portion 11t and the lower portion 11b, may have a height that is substantially smaller than half of a total height of the gate electrode 11. For example, a ratio between a height of the lower portion 11b and the top portion 11t of the shaped gate structure 11 may be substantially less than 0.5, e.g., ≧0.4, or ≧1/3, or ≧1/4, or ≧1/5.

After a complete reading of the present disclosure, the person skilled in the art will appreciate that the semiconductor device 1a may provide the shaped gate structure 5 to reduce a parasitic capacitance of the shaped gate structure 11 to the raised source/drain regions 7 by means of an increased upper thickness t₂ of the spacer structure 9 adjacent to the top portion 11t of the gate electrode 11, while maintaining a good overlap, a good capacitance Cmiller value (the Miller capacitance due to parasitic capacitance between the output and input of active devices like transistors and vacuum tubes is a major factor limiting their gain at high frequencies) by having the lower portion 11b of greater dimension along the gate length of the shaped gate structure 5 as compared to the top portion 11t. Herein, an AC performance of the semiconductor device 1a may be improved or maintained, together with an improved or maintained DC performance, as compared to known semiconductor devices.

FIG. 1b schematically shows a semiconductor device 1b, comprising a shaped gate structure 19 formed over an active region of a substrate 3 as described above with regard to FIG. 1a. The substrate 3 may thus be a substrate having an SOI configuration, comprising a base substrate (not illustrated), a buried insulating material (not illustrated) interposed between the base substrate (not illustrated) and an active semiconductor material (the illustrated portion of the substrate 3 in FIG. 1b may be an upper surface portion of an active semiconductor material) formed on the buried insulating material (not illustrated). In accordance with some special illustrative examples herein, the substrate 3 may be provided in accordance with FDSOI techniques, wherein a thickness of an active semiconductor material (in this case only illustrated as an upper surface portion of the substrate 3 in FIG. 1b) may have a thickness of about 20 nm or less, e.g., a thickness of about 6-10 nm.

In accordance with some illustrative embodiments of the present disclosure, raised source/drain regions 7 may be formed at opposing sides of the shaped gate structure 19. A separation between the raised source/drain region 7 and the shaped gate structure 19 may be adjusted by means of a spacer structure 29. In accordance with some illustrative embodiments of the present disclosure, the spacer structure 29 may comprise at least one spacer, e.g., a “spacer zero,” an optional “spacer one” and at least one optional “spacer liner” and the like. The spacer structure 29 may be formed by at least one layer comprising a silicon oxide material and/or at least one layer comprising a silicon nitride material. In accordance with some illustrative examples, the spacer structure 29 may comprise a low-k material, e.g., SiBCN.

In accordance with some illustrative embodiments of the present disclosure, the shaped gate structure 19 comprises a gate dielectric layer 23. For example, the gate dielectric layer 23 may be formed by a silicon oxide material and/or at least one high-k material, e.g., a hafnium oxide material, such as hafnium oxide, hafnium oxynitride or hafnium silicate. In some illustrative examples, at least one optional work function adjusting material layer 25 may be formed on the gate dielectric layer 23, e.g., a layer of TiN and the like.

In accordance with some illustrative embodiments of the present disclosure, a gate electrode 21 may be disposed over the gate dielectric layer 23, wherein the gate electrode 21 may be comprised of a conductive material, e.g., amorphous silicon, polysilicon, a metal or a metal alloy.

In accordance with some illustrative embodiments, the gate electrode 21 may comprise a lower portion 21b and an upper portion or top portion 21t. In the top portion 21t of the gate electrode 21, a gate contact 27, e.g., a silicide contact, may be formed. This does not pose any limitation on the present disclosure and, alternatively, reference numeral 27 may indicate a gate cap covering an exposed upper surface of the top portion 21t of the gate electrode 21.

Referring to FIG. 1b, the shaped gate structure 19 of the semiconductor device 1b may be formed over an active region of the substrate 3. The raised source/drain regions 7 may be formed at opposing sides of the shaped gate structure 19 relative to a length direction of the shaped gate structure 19, which length direction may be oriented in parallel to a direction as indicated by a double-arrow denoted with “a” in FIG. 1b. That is, the length direction may be a gate length direction extending between the raised source/drain regions 7.

With regard to FIG. 1b, the shaped gate structure 19 is shaped such that the gate electrode 21 has a tapering shape according to which a dimension of the gate electrode 21 along the length direction varies from a maximum value (see “a” in FIG. 1b and in the description below) at the lower portion 21b of the gate electrode 21 close to the gate dielectric layer 23 towards a minimal value (see “c” in FIG. 1b and in the description below) at a top portion 21t of the gate electrode 21, as will be explained below in greater detail.

In accordance with some illustrative embodiments of the present disclosure, a dimension of the gate electrode 21 at the top portion 21t of the gate electrode 21, e.g., a dimension of the gate electrode 21 at an upper surface or interface of the top portion 21t of the gate electrode 21 to the contact structure 17 (or gate cap) taken along a length dimension of the shaped gate structure 19, may be substantially smaller than an effective gate length of the shaped gate structure 19, that is, a dimension of the lower portion 21b of the gate electrode 21, e.g., a dimension of the shaped gate structure 1b at an interface between the gate electrode 21 and an underlying material layer, such as the gate dielectric layer 23 and/or the work function adjusting material layer 25. With regard to FIG. 1, reference numeral “a” indicates a dimension of the shaped gate structure 19 taken along the gate length of the shaped gate structure 19, the gate length being measured along a direction parallel to a channel region extending between the raised source/drain regions 7 in an upper surface portion of the substrate 3 below the shaped gate structure 19. The effective gate length “a” may substantially correspond to a maximum value of the gate electrode 21 taken at the lower portion 21b. Reference numeral “c” in FIG. 1b, schematically indicates a dimension of the gate electrode 21 at the top portion 21t, e.g., at an interface of the top portion 21t and the contact structure 17 (or gate cap) along the gate length. According to the illustration in FIG. 1b, it is: a>c. In other words, the shaped gate structure 19 may have a lower portion 21b having a maximum value measured along the gate length of the shaped gate structure 19, and a dimension of the gate electrode 21 may decrease from the lower portion 21b to the top portion 21t of the gate electrode from the maximum value to a minimum value represented by reference numeral “c” in FIG. 1b. In accordance with some illustrative examples, a dimension of the gate electrode 21 taken along the gate length may decrease at the lower portion 21b, e.g., may linearly decrease at the lower portion 21b to the top portion 21t of the gate electrode 21 (as indicated by reference numeral “c” in FIG. 1b).

In accordance with some special illustrative examples herein, the maximum value “a” may be greater than 25 nm or greater than 30 nm. For example, the maximum value “a” may be in a range from about 25-40 nm, e.g., in a range from about 30-38 nm. In accordance with some explicit but non-limiting examples, the maximum value “a” may be in a range from about 33-37 nm.

In accordance with some special illustrative examples herein, the minimum value “c” may be smaller than 30 nm or smaller than 25 nm. For example, the minimum value “c” may be in a range from about 10-25 nm, e.g., in a range from about 15-23 nm. In accordance with some explicit but non-limiting examples, the minimum value “c” may be in a range from about 16-21 nm.

In accordance with some illustrative embodiments, a dimension of the gate dielectric layer 23 and/or of the optional work function adjusting material layer 25 may be at the target critical dimension, e.g., 32 nm or 22 nm, while the gate electrode may have an equal or smaller maximum value due to the tapering of the gate electrode 21.

In accordance with some illustrative embodiments of the present disclosure, the entire gate electrode 21 may have a tapering shape, e.g., linearly tapering shape, where a tilt angle β formed between a tapering sidewall surface 21s of the gate electrode 21 is tilted relative to an interface “ib” between the gate electrode 21 and the next lower material layer (one of the material layers 23 and 25 in FIG. 1b) may be smaller than 90° (β<90°). In accordance with some illustrative embodiments herein, the tilt angle β may be greater than 60° (60°≦β). For example, the tilt angle β may be in a range from about 70-88° (70°≦β≦88°), or in a range from about 75-88° (75°≦β≦88°), or in a range from about 70-80° (70°≦β≦80°), or in a range from about 60-75° (60°≦β≦75°).

In accordance with some special illustrative example, the tapering of the gate electrode 21 may be linear and the tilt angle β may be substantially constant along the tapering sidewall surface 21s of the gate electrode 21.

In accordance with some illustrative embodiments of the present disclosure, a tilt angle φ defined as a tilting between the tapering sidewall surface 21s relative to an upper surface of the gate electrode 21 at the top portion 21t is substantially equal to 180°−β(φ=180°−β).

In accordance with some illustrative embodiments as depicted with regard to FIG. 1b, the semiconductor device 1b having the shaped gate structure 19 may have a substantially variable separation between the gate electrode 21 and the raised source/drain regions 7 provided by the spacer structure 29 having a variable thickness, that is, a thickness of the spacer structure 29 varying from a minimal thickness t₄ to a maximum thickness t₃ in accordance with the varying dimension of the gate electrode 21 which changes from the maximum value “a” to the minimum value “c”.

After a complete reading of the present disclosure, the person skilled in the art will appreciate that the semiconductor device 1b may provide the shaped gate structure 19 to reduce a parasitic capacitance of the shaped gate structure 19 to the raised source/drain regions 7 by means of an increased upper thickness t₃ of the spacer structure 29 adjacent to the top portion 21t of the gate electrode 21, while maintaining a good overlap, a good capacitance Cmiller value by having the lower portion 21b of greater dimension along the gate length of the shaped gate structure 19 as compared to the top portion 21t. Herein, an AC performance of the semiconductor device 1b may be improved or maintained, together with an improved or maintained DC performance, as compared to known semiconductor devices.

Regarding the shaped gate structure as depicted in FIG. 1b, a trapezoidal shape may be provided.

FIG. 1c schematically shows a semiconductor device 1c, comprising a shaped gate structure 31 formed over an active region of a substrate 3. The substrate 3 may be substantially equal to the substrate 3 as described above and, thus, a substrate having an SOI configuration may be provided, the substrate comprising a base substrate (not illustrated), a buried insulating material (not illustrated) interposed between the base substrate (not illustrated) and an active semiconductor material (the illustrated portion of the substrate 3 in FIG. 1c may be an upper surface portion of an active semiconductor material) formed on the buried insulating material (not illustrated). In accordance with some special illustrative examples herein, the substrate 3 may be provided in accordance with FDSOI techniques, wherein a thickness of an active semiconductor material (in this case only illustrated as an upper surface portion of the substrate 3 in FIG. 1c) may have a thickness of about 20 nm or less, e.g., a thickness of about 6-10 nm.

In accordance with some illustrative embodiments of the present disclosure, raised source/drain regions 7 may be formed at opposing sides of the shaped gate structure 31. A separation between the raised source/drain region 7 and the shaped gate structure 31 may be adjusted by means of a spacer structure 39. In accordance with some illustrative embodiments of the present disclosure, the spacer structure 39 may comprise at least one spacer, e.g., a “spacer zero,” an optional “spacer one” and at least one optional “spacer liner” and the like. The spacer structure 39 may be formed by at least one layer comprising a silicon oxide material and/or at least one layer comprising a silicon nitride material. In accordance with some illustrative examples, the spacer structure 39 may comprise a low-k material, e.g., SiBCN.

In accordance with some illustrative embodiments of the present disclosure, the shaped gate structure 31 comprises a gate dielectric layer 35. For example, the gate dielectric layer 35 may be formed by a silicon oxide material and/or at least one high-k material, e.g., a hafnium oxide material, such as hafnium oxide, hafnium oxynitride, etc. In some illustrative examples, at least one optional work function adjusting material layer 37 may be formed on the gate dielectric layer 35, e.g., a layer of TiN and the like.

In accordance with some illustrative embodiments of the present disclosure, a gate electrode 33 may be disposed over the gate dielectric layer 35, wherein the gate electrode 33 may be comprised of a conductive material, e.g., amorphous silicon, polysilicon, a metal or a metal alloy.

In accordance with some illustrative embodiments, the gate electrode 33 may comprise a lower portion 33b and an upper portion or top portion 33t. In the top portion 33t of the gate electrode 33, a gate contact 37, e.g., a silicide contact, may be formed. This does not pose any limitation on the present disclosure and, alternatively, reference numeral 37 may indicate a gate cap covering an exposed upper surface of the top portion 33t of the gate electrode 33.

Referring to FIG. 1c, the shaped gate structure 31 of the semiconductor device 1c may be formed over an active region of the substrate 3. The raised source/drain regions 7 may be formed at opposing sides of the shaped gate structure 31 relative to a length direction of the shaped gate structure 31, which length direction may be oriented in parallel to a direction as indicated by a double-arrow denoted with “a” in FIG. 1c. That is, the length direction may be a gate length direction extending between the raised source/drain regions 7.

With regard to FIG. 1c, the shaped gate structure 31 is shaped such that the gate electrode 33 has a varying length dimension, that is, a length dimension of the gate electrode 33 varies along a height of the gate electrode 33 (wherein “height” of the gate electrode 33 in FIG. 1c is understood as perpendicular to the length direction “a” in the paper plane) leading to a tapering shape of the gate electrode 33 along a part of its height. For example, a dimension of the gate electrode 33 along the length direction varies from a maximum value (see “d” in FIG. 1c and in the description below) at the lower portion 33b of the gate electrode 33 close to the gate dielectric layer 35 towards a minimal value (see “e” in FIGS. 1c and 1n the description below) at a top portion 33t of the gate electrode 33, as will be explained below in greater detail.

In accordance with some illustrative embodiments of the present disclosure, a dimension of the gate electrode 33 at the top portion 33t of the gate electrode 33, e.g., a dimension of the gate electrode 33 at an upper surface or interface of the top portion 33t of the gate electrode 33 to the contact structure 37 (or gate cap) taken along a length dimension of the shaped gate structure 31, may be substantially smaller than an effective gate length of the shaped gate structure 31, that is, a dimension of the lower portion 33b of the gate electrode 33, e.g., a dimension of the shaped gate structure 31 at an interface between the gate electrode 33 and an underlying material layer, such as the gate dielectric layer 35 and/or the work function adjusting material layer 37. With regard to FIG. 1c, reference numeral “a” indicates a dimension of the shaped gate structure 31 taken along the gate length of the shaped gate structure 31, the gate length being measured along a direction parallel to a channel region extending between the raised source/drain regions 7 in an upper surface portion of the substrate 3 below the shaped gate structure 31. The effective gate length “a” may substantially correspond to a maximum value of the gate electrode 33 taken at the lower portion 33b. Reference numeral “e” in FIG. 1c schematically indicates a dimension of the gate electrode 33 at the top portion 33t, e.g., at an interface of the top portion 33t and the contact structure 37 (or gate cap) along the gate length. According to the illustration in FIG. 1c, it is: a>e. In other words, the shaped gate structure 31 may have a lower portion 33b having a dimension “a” measured along the gate length of the shaped gate structure 31, and the dimension of the gate electrode 33 may decrease from “a” at the lower portion 33b to the top portion 33t of the gate electrode from a minimum value represented by reference numeral “e” in FIG. 1c (a>e). In accordance with some illustrative examples, a dimension of the gate electrode 33 taken along the gate length may decrease at the lower portion 33b, e.g., may increase at the lower portion 33b to a belly portions or convexity 43 at certain height level of the gate electrode 33 where a maximum value “d” may be provided (d>a) and may then substantially decrease along the gate electrode 33 towards the top portion 33t to result in the minimum value “e” (e<a, d). The dimension may at least linearly (linearly or to a higher order, such as according to a quadratic or even higher order behavior) increase towards the belly or convexity 43 and may at least linearly (linearly or to a higher order, such as according to a quadratic or even higher order behavior) decrease towards the minimum value e at the top portion 33t of the gate electrode 33.

In accordance with some illustrative embodiments as depicted with regard to FIG. 1c, the semiconductor device 1c having the shaped gate structure 31 may have a substantially variable separation between the gate electrode 33 and the raised source/drain regions 7 provided by the spacer structure 39 having a variable thickness, that is, a thickness of the spacer structure 39 varying from a small thickness t₅ over a minimum thickness t₇ at the belly 43 to a maximum thickness t₆ in accordance with the varying dimension of the gate electrode 33 which changes from the maximum value “d” to the minimum value “e”.

In accordance with some illustrative embodiments of the present disclosure, the belly 43 may represent a transition between the top portion 33t and the lower portion 33b and may be located at a height level (first height level) along the gate electrode 33, substantially smaller than half of a total height of the gate electrode 33. For example, a ratio between a height of the lower portion 33b to the belly 43 at the maximum value “d” and the top portion 33t of the shaped gate structure 33 (a remaining height of the gate electrode over the first height level) may be substantially equal to or less than 0.5, e.g., ≧1/3, or ≧1/4, or ≧1/5, or ≧1/6, or ≧1/7, or ≧1/8, or ≧1/9, or ≧1/10.

In accordance with some special illustrative examples herein, the value “a” may be greater than 22 nm or greater than 30 nm. For example, the value “a” may be in a range from about 22-40 nm, e.g., in a range from about 25-33 nm. In accordance with some explicit but non-limiting examples, the value “a” may be in a range from about 33-37 nm.

In accordance with some special illustrative examples herein, the maximum value “d” may be greater or equal to the value “a” (in which case both values “a” and “d” are identified with the “maximum value”). For example, the maximum value “d” may be greater than 22 nm or greater than 30 nm. For example, the maximum value “d” may be in a range from about 22-40 nm, e.g., in a range from about 23-33 nm. In accordance with some explicit but non-limiting examples, the maximum value “d” may be in a range from about 33-37 nm.

In accordance with some special illustrative examples herein, the minimum value “e” may be smaller than 30 nm or smaller than 25 nm. For example, the minimum value “e” may be in a range from about 10-25 nm, e.g., in a range from about 15-23 nm. In accordance with some explicit but non-limiting examples, the minimum value “e” may be in a range from about 16-21 nm.

In accordance with some illustrative embodiments, a dimension of the gate dielectric layer 35 and/or of the optional work function adjusting material layer 37 may be at the target critical dimension, e.g., 32 nm or 22 nm, while the gate electrode may have an equal or smaller maximum value due to the tapering of the gate electrode 33.

In accordance with some illustrative embodiments of the present disclosure, only the top portion 33t of the gate electrode 33 may have a tapering shape towards the minimum value “e”, e.g., a linearly tapering shape, where a tilt angle δ formed between a tapering sidewall surface 33s of the gate electrode 33 is tilted relative to an upper surface of the gate electrode 33 at the top portion 33t. For example, the tilt angle δ may be greater than 90° (δ>) 90°. In accordance with some illustrative embodiments herein, the tilt angle δ may be smaller than 150° (150°≦δ). For example, the tilt angle δ may be in a range from about 95-130° (95°≦δ≦130°), or in a range from about 95-120° (95°≦δ≦120°), or in a range from about 100-120° (100°≦δ≦120°), or in a range from about 100-110° (100°≦δ≦110°).

In accordance with some special illustrative examples, the tapering of the gate electrode 33 may be linear and the tilt angle δ may be substantially constant along the tapering sidewall surface 33s of the gate electrode 33.

In accordance with some illustrative embodiments of the present disclosure, a tilt angle γ defined as a tilting between an upwardly tapering sidewall surface 33u at the interface of the gate electrode 33 and a material layer below (one of the layers 35 and 37) at the lower portion 33b may be substantially equal to δ (γ≈δ, wherein abs(γ−δ)<30°, or abs(γ−δ)<15°, or abs(γ−δ)<10°, or abs(γ−δ)<5°).

After a complete reading of the present disclosure, the person skilled in the art will appreciate that the semiconductor device 1c may provide the shaped gate structure 31 to reduce a parasitic capacitance of the shaped gate structure 31 to the raised source/drain regions 7 by means of an increased upper thickness t₆ of the spacer structure 39 adjacent to the top portion 33t of the gate electrode 33, while maintaining a good overlap, a good capacitance Cmiller value by having the lower portion 33b of greater dimension along the great length of the shaped gate structure 31 as compared to the top portion 33t. Herein, an AC performance of the semiconductor device 1c may be improved or maintained, together with an improved or maintained DC performance, as compared to known semiconductor devices.

Regarding the shaped gate structure 31 as depicted in FIG. 1c, a teardrop-shape may be provided.

It is pointed out that the dimension “a” as indicated above with regard to FIGS. 1a-1c may be considered as substantially equal as the dimension “a” may be substantially set in accordance with a target critical dimension of the semiconductor device under design.

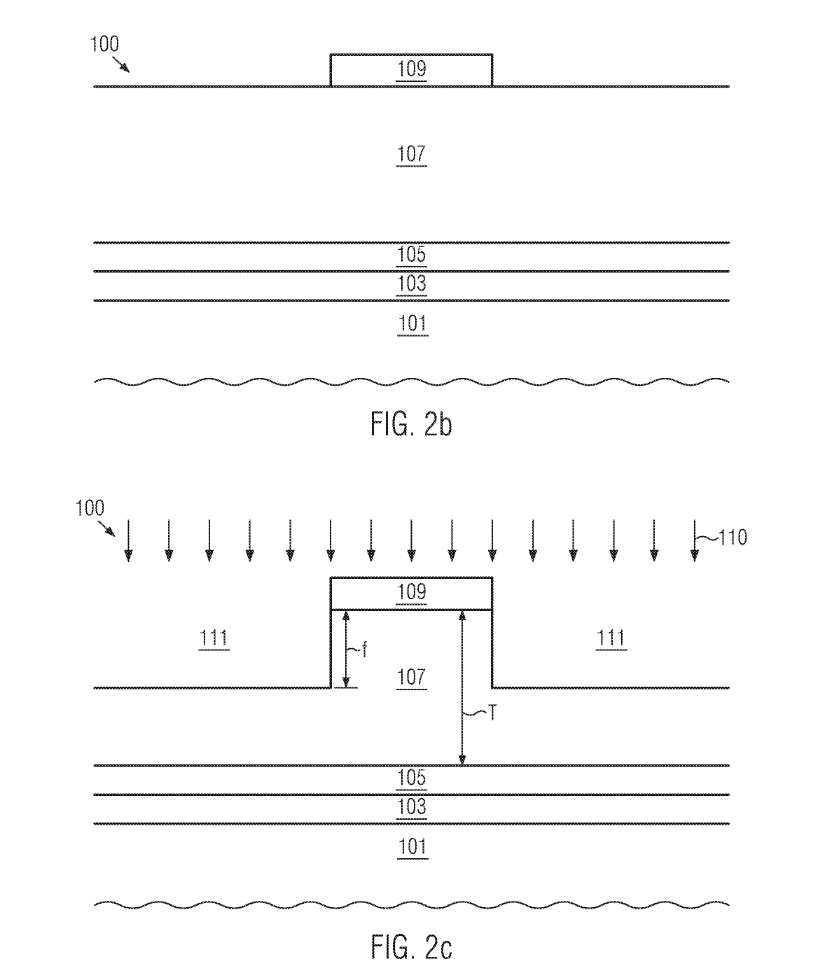

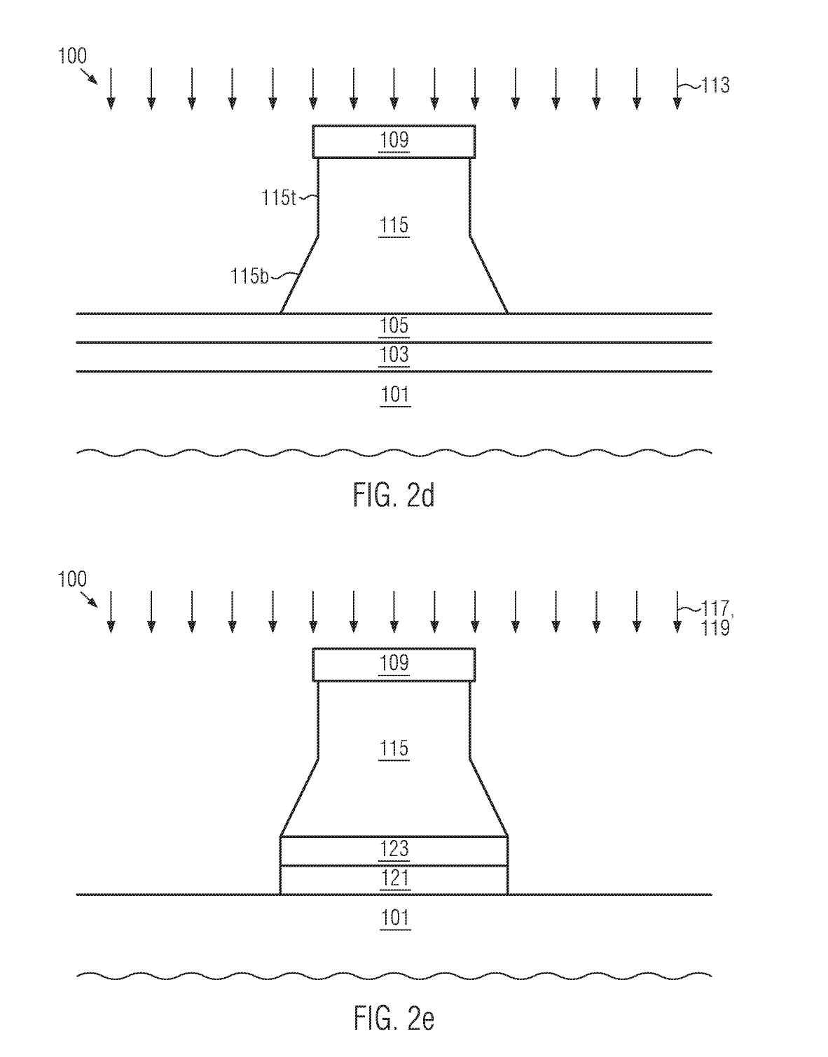

With regard to FIGS. 2a-2d, a method of forming a semiconductor device in accordance with some illustrative embodiments of the present disclosure will be described. Herein, FIGS. 2a-2d schematically illustrate cross-sectional views of a portion of a semiconductor device 100 at various stages during fabrication in and over an active region formed in a substrate 101. The substrate 101 may be similar to the substrate 3 as described above, therefore, an according description of the substrate 101 is omitted here.

FIG. 2a schematically illustrates the semiconductor device 100 at an early stage during fabrication, e.g., at an early stage of a front-end-of-line (FEOL) process during which a gate structure is formed. At the stage illustrated in FIG. 2a, gate material layers 103, 105 and 107 may be deposited over the substrate 101. In accordance with some illustrative examples herein, the gate material layers 103, 105 and 107 may be deposited by known deposition techniques, e.g., atomic layer deposition (ALD) and/or physical vapor deposition (PVD) and/or chemical vapor deposition (CVD) and/or a mixture thereof. In accordance with some illustrative examples herein, a gate dielectric material layer 103 may be deposited over the substrate 101 by forming a silicon oxide material layer and/or depositing at least one high-k material layer over the substrate 101. Subsequently, an optional work function adjusting material layer 105 may be deposited over the substrate 101. Subsequently, a gate electrode conductive material layer 107 may be deposited over the substrate 101 by forming one of, e.g., amorphous silicon, polysilicon, a metal or a metal alloy over the substrate 101.

With regard to FIG. 2b, the semiconductor device 100 is schematically illustrated at a more advanced stage during fabrication, at which a masking pattern 109 is formed over the gate electrode material layer 107, the masking pattern 109 being formed for patterning the deposited gate material layers 103, 105 and 107 to subsequently form a gate stack in accordance with a desired gate pattern over the substrate 101. In accordance with some illustrative examples, the mask pattern 109 may be formed by known photolithography techniques, e.g., depositing a photoresist and lithographically patterning the deposited photoresist. The gate mask pattern 109 may comprise multiple hard mask structure layers, though this does not pose any limitation to the present disclosure and the mask pattern 109 may only be a patterned photoresist.

FIGS. 2c-2d schematically illustrate the semiconductor device 100 at a more advanced stage during fabrication, at which stage a process sequence is performed. Particularly, FIG. 2c schematically illustrates the semiconductor device 100 during the process sequence at a stage when the process sequence is not yet completed.

With regard to FIG. 2c, the semiconductor device 100 is schematically illustrated at the end of a first dry etch step of the process sequence, e.g., a reactive ion etch (RIE) step, or a plasma etch step or sputter etch step. The first dry etch step may have a first degree of anisotropy. Generally, the degree of anisotropy may be defined as a measure of how rapidly an agent removes material in different directions. For example, a given agent employed in an etching process has different etch rates acting in different directions. Particularly, an anisotropic agent may have an etching rate R_{V} Acting Along a Vertical Direction, that is, Along a direction normal to an upper surface of the gate electrode material layer 107 in FIG. 2b, indicating an amount of material removed over time and/or a thickness of removed material over time (e.g., an etch rate of 1 nm/second indicates a removal of 1 nm of a given material layer per second). Furthermore, there is an etch rate acting horizontally, that is, parallel to an upper surface of the gate electrode material 107 in FIG. 2b, this etch rate being indicated by R_{H}. On the basis of the ratio R_{H}/R_{V}, the degree of anisotropy A may be defined, e.g., the degree of anisotropy may be defined as: A=1−(R_{H}/R_{V}). Herein, A=1 indicates a complete anisotropic etching process, while A=0 indicates a completely anisotropic etching process. The first degree of anisotropy of the first dry etch step may be indicated by A₁. In accordance with some illustrative embodiments of the present disclosure, the first degree of anisotropy A₁ may be greater than 0.19, e.g., greater than 0.75 or greater than 0.9.

In accordance with some illustrative embodiments of the present disclosure, the first dry etch process 110 may be time controlled to form recesses 111 in the gate electrode material layer 107 in alignment with the mask pattern 109, wherein the recesses 111 only partially extend into the gate electrode material layer 107. In accordance with some illustrative examples herein, a depth of the recesses 111 may be denoted by f, and upon denoting a total thickness of the gate electrode material layer 107 by reference numeral T as depicted in FIG. 2c, a ratio f/T is smaller than 1. In accordance with some special illustrative examples herein, f/T may be greater than 0.19, e.g., may be in a range from about 0.6-0.9. This does not pose any limitation to the present disclosure and the person skilled in the art will appreciate that any appropriate ratio f/T may be adjusted by appropriately selecting an etching time for the first dry etch step.

Referring to FIG. 2d, the semiconductor device 100 is schematically illustrated at a stage during fabrication at which a second dry etch step following the first dry etch step is completed. The second dry etch step may be configured to have a second degree of anisotropy A₂, wherein A₂ is smaller than A₁ (A₂<A₁). For example, A₂ may be smaller than 0.19.

In accordance with some illustrative embodiments of the present disclosure, the second dry etch step may use the underlying material layer, that is, one of the material layers 103 and 105, as an etch stop such that the bottom of the trenches 111 in FIG. 2c may be anisotropically etched during the second dry etch process 113 so as to expose an upper surface of the underlying material layer. As the second degree of anisotropy A₂ is smaller than the first degree of anisotropy, the accordingly obtained shaped gate electrode 115 has two wall portions 115b and 115t, wherein an angle between the wall portion 115b relative to a normal direction to an upper surface of a material layer below is greater than an angle between the wall portion 115t and the normal to the upper surface of a lower material layer. In other words, the wall portion 115b is “less vertical than the portion 115t.” In this way, a tapering gate electrode 115 may be formed, the gate electrode 115 having at least a tapering portion, that is the wall portion 115b, which has a maximum value towards the interface between the gate electrode 115 and a lower material layer, i.e., one of the material layers 105 and 103.

In accordance with some special illustrative examples herein, the first and second dry etch steps 110 and 113 may comprise at least one fluorine comprising gas component, e.g., SF₆ and/or NF₃ and/or a fluorocarbon gas, such as CF₄ and/or C₂F₆ and/or CH₂F₂. A concentration of the at least one fluorine comprising gas component in the first dry etch step may be smaller than a concentration of the at least one fluorine comprising gas component in the second dry etch step.

The first dry etch step 110 may alternatively comprise at least one fluorine comprising gas component, e.g., SF₆ and/or NF₃ and/or a fluorocarbon gas, such as CF₄ and/or C₂F₆ and/or CH₂F₂, whereas the second dry etch step 113 may comprise at least one bromide comprising gas component, e.g., HBr. A concentration of the at least one fluorine comprising gas component in the first dry etch step may be smaller than a concentration of the at least one bromide comprising gas component in the second dry etch step.

Although the above description explicitly describes a first dry etch step and a second dry etch step, this does not pose any limitation to the present disclosure and the person skilled in the art will appreciate after a complete review of the present disclosure that more than two dry etch steps may be implemented, a degree of anisotropy of a possible third dry etch step (not illustrated) being smaller than the second degree of anisotropy, a possible fourth dry etch step (not illustrated) having a fourth degree of anisotropy smaller than the third degree of anisotropy and so on. Alternatively, a single dry etch step having varying gas ratio change throughout the etch step may be used instead of the first and second dry etch steps.

Regarding FIG. 2e, the semiconductor device 100 is schematically illustrated after a sequence of process steps 117, 119 is completed, the sequence of process steps 117, 119 being used for anisotropically etching the deposited material layers 105 and 103 resulting in a gate dielectric layer 121 and an optional work function adjusting material layer 123. In accordance with some alternative embodiments, these layers can also be under-etched to have further control of gate targeting.

In accordance with the various illustrative embodiments as described above with regards to FIGS. 2a-2e, a shaped gate structure as described with regard to FIG. 1a may be obtained. This does not pose any limitation to the present disclosure and the person skilled in the art will appreciate that a shaped gate structure as illustrated in FIG. 1b may be obtained by omitting the first etch step as described above with regard to FIG. 2c and performing an etching process of the deposited gate electrode material layer 107 (FIG. 2b) by means of an etch process that has a desired degree of anisotropy such that the sidewalls of the etched gate electrode material layer are slanted relative to a normal direction of an upper surface of the deposited gate electrode material layer to a certain degree for implementing a trapezoidal gate electrode as schematically illustrated in FIG. 1b.

Regarding a shaped gate structure as schematically illustrated in FIG. 1c, the person skilled in the art will appreciate that, upon employing a method as schematically described above with regard to FIGS. 2a-2d, two etch steps may be employed, the two etch steps involving a first etch step which is less polymerizing than the second etch step to form the top trapezoidal shape, and having a third/fourth etch step to etch the material layers 105 and 103, which also rounds the bottom part of the gate electrode 115 forming the final teardrop shape.

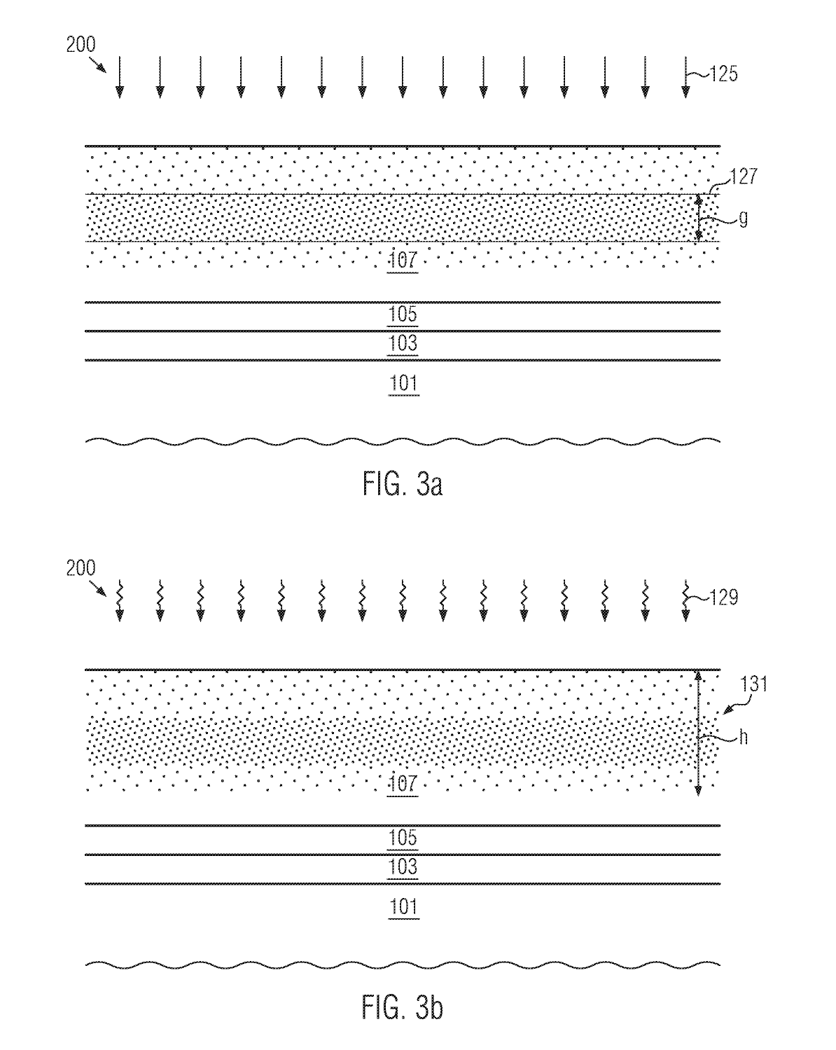

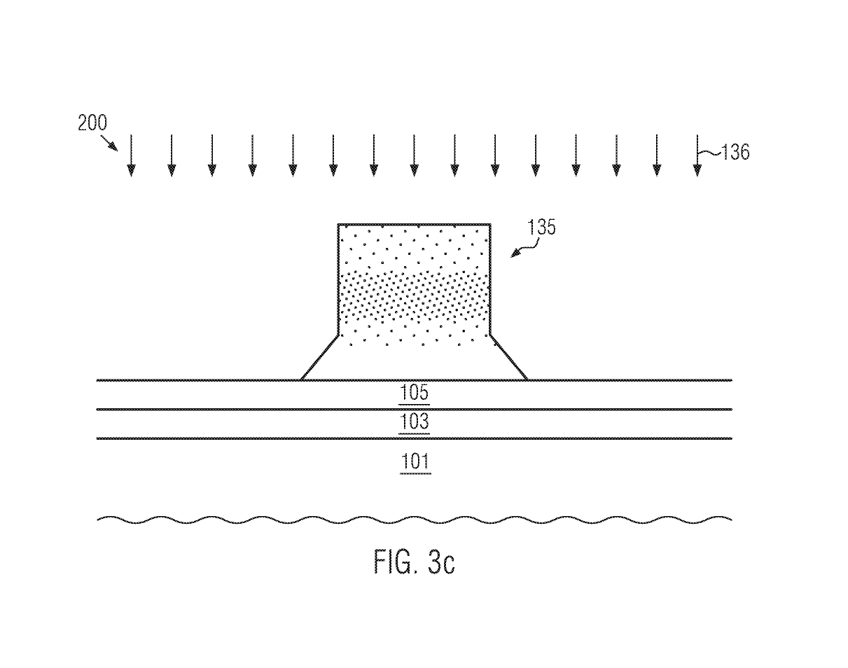

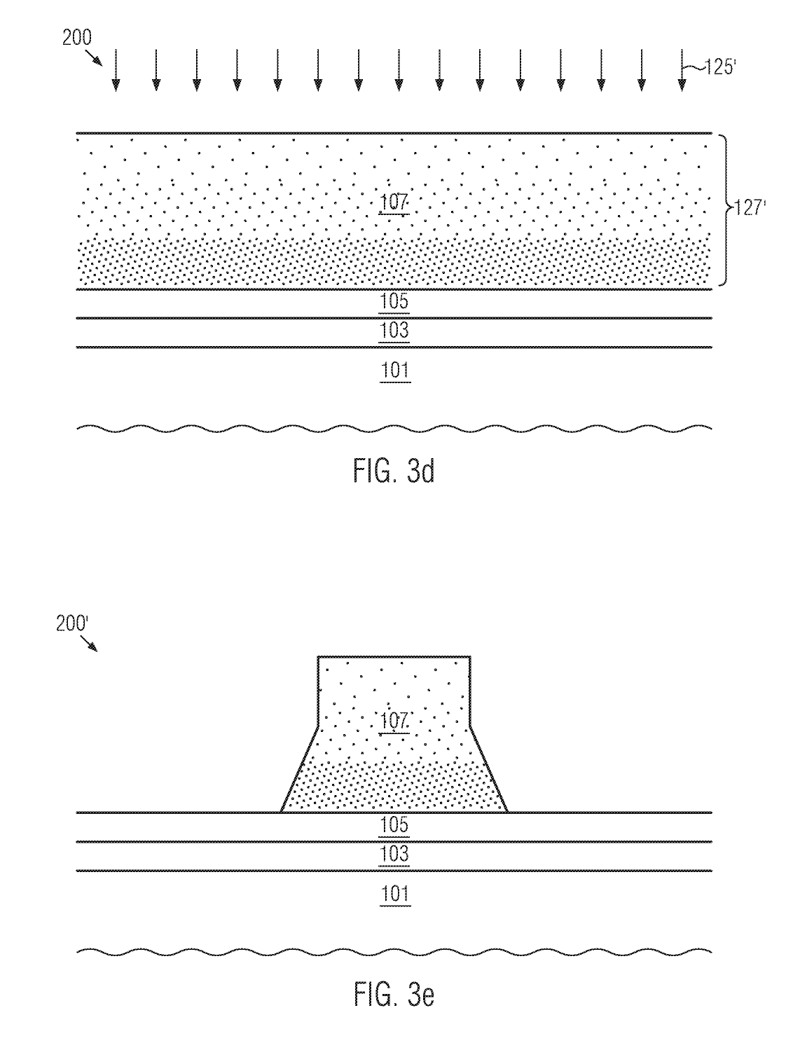

With regard to FIGS. 3a-3c, other illustrative embodiments of the present disclosure will be described. FIG. 3a schematically illustrates a semiconductor device 200 at an early stage during processing, particularly at a stage during processing subsequent to the stage that is schematically illustrated in FIG. 2a and wherein an implantation process 125 is performed to implant dopants into the gate electrode material layer 107. In accordance with some illustrative embodiments of the present disclosure, the implantation of dopants as achieved via the implantation process 125 leads to a doped region 127 within the gate electrode material layer 107, in which doped region 127 a level of doping is at least 70% of dopants. As schematically illustrated in FIG. 3a, dopants are also encountered outside the doped region 127, although the concentration of dopants outside the doped region 127 is very low. Accordingly, the doped region 127 may be considered as a layer of dopants having a thickness as indicated by reference numeral “g” in FIG. 3a.

With regard to FIG. 3d, some alternative embodiments of the present disclosure are shown, wherein an implantation process 125′ is performed instead of the implantation process 125 as described above. The implantation process 125′ may be configured to implement a doping profile 127′ within the gate electrode material layer 107, wherein the entire gate electrode material layer 107 may be doped. In accordance with some illustrative examples herein, the doping profile 127′ may be formed so as to have the highest concentration of doping at the base of layer 107, allowing for a slower etch during a subsequent etch process (not illustrated) close to an interface between the gate electrode material layer 107 and the underlying material layers. In accordance with some illustrative embodiments herein, the implantation process 125′ may comprise implanting arsenic into the gate electrode material layer 107.

In accordance with some illustrative embodiments of the present disclosure, the dopants may be selected upon at least one of phosphorous, arsenic, and boron. For example, the implantation of dopants may be performed when pre-doping gate electrode structures having a gate electrode formed by polysilicon or amorphous silicon.

In accordance with some illustrative embodiments of the present disclosure, the dopants may be implanted at an energy of at least 4 keV, e.g., phosphorous may be implanted at an energy of about 6 keV and arsenic may be implanted at an energy of about 6 keV. For example, dopants may be implanted at energies up to 24 keV.

In accordance with some illustrative embodiments of the present disclosure, a dose at which the dopants may be implanted may be on the order of about 10¹⁵ cm⁻². In accordance with some explicit examples herein, phosphorous may be implanted at a dose of about 1-9×10¹⁵ cm⁻². For example, arsenic may be implanted at a dose of about 4×10¹⁵ cm⁻². This does not pose any limitation to the present disclosure and the person skilled in the art will appreciate that an appropriate dose may be chosen to implement an appropriate concentration of dopants within the doped region 127.

With regard to FIG. 3b, the semiconductor device 200 is schematically illustrated at a more advanced stage during fabrication at which an annealing process 129 is performed. The annealing process 129 may comprise exposing the semiconductor device 200 to a temperature of at least 400° C., e.g., to a temperature of at least 800° C., such as to a temperature at about 1065° C. This does not pose any limitation to the present disclosure and the person skilled in the art will appreciate that a temperature profile for the annealing process 129 may be adjusted for implementing a certain concentration profile of dopants implanted into the gate electrode material layer 107 in the previous implantation process 125.

As schematically illustrated in FIG. 3b, the dopants implanted into the gate electrode material layer 107 are distributed within the gate electrode material layer 107 over a substantially broad surface region as indicated by reference numeral “h” in FIG. 3b representing a thickness of a doped upper surface region 131 of the gate electrode material layer 107.

With regard to FIG. 3c, the semiconductor device 200 is schematically illustrated at a more advanced stage during fabrication after an etching process 136 is applied to the semiconductor device 200 subsequent to the annealing process 129 in FIG. 3b. As a result of the anisotropic etching process (not illustrated), a shaped gate electrode 135 is obtained in dependence on the distributed dopants within the gate electrode material layer prior to the anisotropic etching (not illustrated). The person skilled in the art will appreciate that doped gate electrode material may have a higher etch rate when compared to undoped gate electrode material, particularly, the etch rate increases with a concentration of dopants within the gate electrode material, e.g., in the case of phosphorous and/or boron being used as dopants during the implantation process 125 in FIG. 3a. After a complete reading of the present disclosure, the person skilled in the art will appreciate that, upon appropriately adjusting a dopant concentration profile within the gate electrode material layer, due to different etch rates of doped gate electrode material versus undoped gate electrode material, an appropriate shaping of the deposited gate electrode material may be subsequently obtained after performing an anisotropic etching process (not illustrated).

With regard to FIG. 3e, a semiconductor device 200′ in accordance with some alternative embodiments of the present disclosure is illustrated, wherein the annealing processes 129 as described above with regard to FIG. 3b is performed subsequent to the implantation process 125′ as depicted in FIG. 3d. Due to the implantation process 125′, the highest concentration of dopants may be located closer to the material layer 105 and the entire gate electrode material layer 107 may be doped (i.e., h would reach across the entire gate electrode material layer 107), e.g., doped with arsenic. Upon applying an etch process which is configured such that a higher concentration of dopants leads to a slower etch rate, the bottom region of the gate electrode material layer 107 having the highest concentration of dopants is etched more slowly than an upper portion of the gate electrode material layer 107. Accordingly, the semiconductor device structure 200′ as depicted in FIG. 3e is obtained.

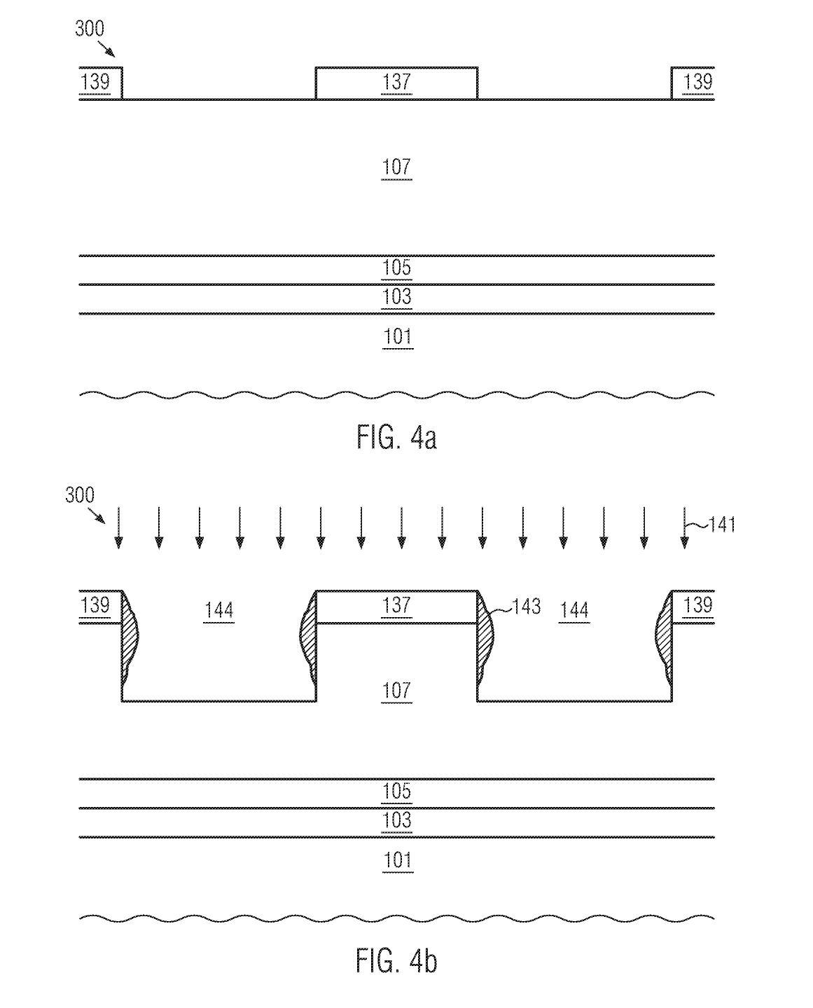

With regard to FIG. 4a, a semiconductor device 300 is schematically illustrated at a stage during fabrication which follows the stage that is illustrated in and described above with regard to FIG. 2a, wherein a masking pattern 137, 139 is formed in accordance with a desired gate pattern.

With regard to FIG. 4b, the semiconductor device 300 is schematically illustrated at a more advanced stage during fabrication at which an anisotropic etch process 141 is performed. Performing the anisotropic etch process 141 may comprise feeding a reactant having polymerizing and non-polymerizing constituents to the semiconductor device 300, the polymerizing constituents leading to a passivation 143 of sidewalls of etched trenches 144 caused by formation of a polymer on the sidewalls of the trenches 144. In accordance with a special illustrative example herein, a ratio of polymerizing constituents may be increased during the anisotropic etch process.

In accordance with some illustrative embodiments of the present disclosure, the anisotropic etching process 141 may comprise a controlled polymer deposition on the sidewalls of the etched trenches 144 during the etching process, wherein a polymer is deposited on the sidewalls while the etching proceeds in an anisotropic fashion. For example, upon using a plasma etch process, where the bottom of the trenches 144 are etched due to the bombardment of the bottom of the trenches, the trenches 144 are progressively etched, while the sidewalls of the trenches 144 at the top of the trenches 144 are increasingly coated with a progressively thicker polymer. Since the etching at the bottom of the trenches 144 is anisotropic, the deposited polymer 143, that is the increasing passivation 143, builds up at the top of the trenches 144, increasing shadowing of the bottom of the hole. Therefore, the diameter of the trenches 144 is progressively decreased, resulting in a tapering of the trenches 144. A control of the rate of polymer deposition 143 on the sidewalls of the trenches can be achieved by adjusting the chemistry of the ratio of the polymerizing versus non-polymerizing components of the reactant fed during the anisotropic etch process. In accordance with some special illustrative examples herein, the ratio of CHF₃ and CF₄ gases in a CHF₃/CF₄ feed gas mixture or a ratio of SF₆ to CH₂F₂ may be appropriately varied. By increasing the percentage of CHF₃ or CH₂F₂ in such a mixture, the polymer deposition rate (and hence an angle of the sidewall taper) may be increased. In accordance with other explicit examples, mixtures of C₄F₈/N₂, C₄F₈/Ar/CO/N₂/O₂ and C₄F₈/CO/CHF₃ may be used.

In accordance with some illustrative examples herein, a temperature of the anisotropic etch process may be adjusted to be substantially smaller than 150° C. For example, at higher temperatures, deeper sidewalls may be produced because the deposition rates of polymers are greater at lower temperatures.

The present disclosure addresses, in accordance with the various illustrative embodiments as described above, the issue of high parasitic fringing capacitances with raised source/drain regions in complex semiconductor devices. In accordance with the various illustrative embodiments of the present disclosure, the parasitic capacitances caused by raised source/drain regions are limited due to an increased spacer thickness adjacent to a portion of a gate electrode, the increased spacer thickness being caused by a shaped gate structure. Herein, a lower portion of the gate, e.g., at the gate dielectric or a lower portion of a gate electrode, are kept at a targeted critical dimension being given by a gate length, e.g., of at most 35 nm. A shaped gate structure may be obtained by changing parameters in a gate etch process, by appropriately adjusting an implantation profile when pre-doping the gate electrode, or upon employing a polymerizing etch process.

After a complete reading of the present disclosure, the person skilled in the art will appreciate that by reducing the parasitic capacitance between the shaped gate structure and the adjacent raised source/drain regions, the AC performance of the semiconductor device may be improved. Furthermore, as the DC performance depends mainly on the gate length and an overlap capacitance (increasing the gate length helps to boost the performance), the shaped gate structures further improve the DC performance as the lower portion of the gate structure is substantially kept at the targeted critical dimension despite any shaping applied to the gate structure. In accordance with some special examples, shaped gate structures may have a shape of a trapezoid, a tear-drop and the like, and the BCD is kept at target but the narrowest spacer thickness is optimized so as to find an optimal spacer thickness at the narrowest point between the gate structure and the raised source/drain regions, at which point the performance is maximized but not compromised by gate leakage. In accordance with some illustrative embodiments of the present disclosure, tear-drop like and trapezoidal like shapes of gate electrodes may be created by tuning the polymerization of a poly step during the fabrication of the gate stack, and an optimal gate profile may be created by adjusting a temperature of a rapid thermal anneal process and the gate length so as to maintain a targeted threshold voltage. By means of a TiN undercut, by forming the work function adjusting material with a smaller critical dimension than the widest critical dimension of the gate electrode, i.e., undercutting the TiN, other adjustments like tuning of Cmiller value can be further performed. The person skilled in the art will appreciate that increasing the gate length helps to boost the performance.

In accordance with at least some of the illustrative embodiments as described above, a less complex process flow for fabricating complex semiconductor devices at advanced technology nodes is provided, the semiconductor devices having lower parasitic capacitances for NMOS and PMOS semiconductor devices as compared to conventional semiconductor devices without incurring additional costs and without requiring an additional CAPEX unlike low-k spacer introduction.

The present disclosure is described with regard to various illustrative embodiments wherein a gate electrode having a tapering shape is formed, according to which a dimension of the gate electrode along a length direction varies from a maximum value at a lower portion of the gate electrode close to the gate dielectric layer towards a minimal value at a top portion of the gate electrode. Illustrative embodiments as depicted in the figures and described above with regard to the figures show the minimal value as a dimension of an upper exposed surface of the gate electrode. This does not pose any limitation to the present disclosure and the person skilled in the art will appreciate that the minimal value may be a dimension at a height level of the gate electrode smaller than a total height of the gate electrode. According gate electrodes may have a neck portion at the top portion, wherein, around the neck portion, a cross-section decreases towards the neck portion and increases when moving away from the neck portion.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a short-hand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. A method of forming a semiconductor device, comprising:
forming a shaped gate structure over an active region, said shaped gate structure comprising a gate dielectric layer and a gate electrode disposed above said gate dielectric layer;
forming a spacer structure adjacent to said shaped gate structure; and
forming raised source/drain regions adjacent to said shaped gate structure and separated from said shaped gate structure by said spacer structure, said raised source/drain regions being formed at opposing sides of said shaped gate structure relative to a gate length direction of said shaped gate structure;
wherein said gate electrode has a tapering shape according to which a dimension of said gate electrode along said gate length direction varies from a maximum value at a lower portion of said gate electrode close to said gate dielectric layer towards a minimal value at a top portion of said gate electrode, and said spacer structure has a vertical sidewall adjacent said raised source/drain regions and a thickness adjacent said gate electrode, said thickness increasing towards said top portion of said gate electrode corresponding to said tapering shape.

2. The method of claim 1, wherein forming said shaped gate structure comprises:
depositing gate material layers over said active region;
patterning said deposited gate material layers, wherein a gate stack is formed; and
partially etching said gate stack such that a dimension of at least one of said gate dielectric layer and said lower portion of said gate electrode along a length dimension of said gate stack is substantially maintained as said maximum value.

3. The method of claim 2, wherein said spacer structure has a thickness increasing at least linearly towards said top portion of said gate electrode.

4. The method of claim 1, wherein said maximum value is substantially equal to a targeted critical dimension.

5. The method of claim 4, wherein said targeted critical dimension is a gate length of at most 35 nm.

6. The method of claim 1, wherein forming said shaped gate structure comprises:
depositing gate material layers over said active region, said gate material layers comprising a gate electrode material layer and a high-k dielectric material;
forming a masking pattern on said deposited gate material layers; and
performing a sequence of anisotropic etch steps in accordance with said masking pattern, wherein said gate electrode material layer is sequentially etched by at least a first dry etch step and a second dry etch step, said at least first and second dry etch steps having different degrees of anisotropy.

7. The method of claim 6, wherein said first dry etch step has a first degree of anisotropy and said second dry etch step has a second degree of anisotropy smaller than said first degree of anisotropy.

8. The method of claim 6, wherein said first and second dry etch steps comprise at least one fluorine-comprising gas component, a concentration of at least one fluorine-comprising gas component in said second dry etch step being greater than a concentration of at least one fluorine-comprising gas component in said first dry etch step.

9. The method of claim 1, wherein forming said shaped gate structure comprises:
depositing gate material layers over said active region, said gate material layers comprising a gate electrode material layer and a high-k dielectric material;
forming a masking pattern on said deposited gate material layers; and
performing an anisotropic etch process in accordance with said masking pattern, said anisotropic etch process comprising feeding a reactant having polymerizing and non-polymerizing constituents.

10. The method of claim 9, wherein a ratio of polymerizing constituents is increased during said anisotropic etch process.

11. The method of claim 9, wherein a temperature of said anisotropic etch process is substantially smaller than 150° C.

12. The method of claim 1, wherein forming said shaped gate structure comprises:
depositing gate material layers over said active region, said gate material layers comprising a gate electrode material layer and a high-k dielectric material;
implanting dopants into said gate electrode material layer;
subsequently performing an annealing process at a temperature of at least 400° C.; and
subsequently applying an etch process to said deposited gate material layers.

13. The method of claim 12, wherein implanting dopants comprises implanting one of phosphorus, arsenic, boron and aluminum.

14. The method of claim 13, wherein said dopants are implanted having at least one of an energy of at least 4 keV and a dose on the order of about 10¹⁵ cm⁻².

15. The method of claim 12, wherein said annealing process comprises a temperature greater than about 800° C.

16.-20. (canceled)
